(19) United States
(12) Patent Application Publication
(10) Pub. No.: US 2022/0115245 A1
(43) Pub. Date: Apr. 14, 2022

(54) POWER SEMICONDUCTOR PACKAGE AND METHOD FOR FABRICATING A POWER SEMICONDUCTOR PACKAGE

(71) Applicant: Infineon Technologies AG, Neubiberg (DE)

(72) Inventors: Jayaganasan Narayanasamy, Melaka - Durian Tunggal (MY); Syahir Abd Hamid, Melaka (MY); Meng How Chong, Melaka (MY); Michael Reyes Godoy, Melaka (MY); Chee Ming Lam, Melaka (MY); Adbul Rahman Mohamed, Johor (MY); Sanjay Kumar Murugan, Melaka (MY); Thomas Stoek, Buxtehude (DE)

(21) Appl. No.: 17/492,865

(22) Filed: Oct. 4, 2021

(30) Foreign Application Priority Data
Oct. 13, 2020 (DE) 102020126857.2

(51) Int. Cl. H01L 21/48; H01L 21/56; H01L 23/495; H01L 23/31

(52) U.S. Cl. CPC H01L 21/4842; H01L 23/3107; H01L 23/49562; H01L 21/565

(57) ABSTRACT

A method for fabricating a power semiconductor package includes: providing a leadframe having a die pad and a frame, wherein the die pad is connected to the frame by at least one tie bar; attaching a semiconductor die to the die pad; laser cutting through the at least one tie bar, thereby forming a cut surface; and after the laser cutting, molding over the die pad and the semiconductor die, wherein the cut surface is completely covered by molding compound.

### TECHNICAL FIELD

This disclosure relates in general to power semiconductor packages as well as to methods for fabricating power semiconductor packages.

### BACKGROUND

Power semiconductor packages may be configured to operate with a high electrical voltage and/or a high electrical current. Power semiconductor packages may therefore have to fulfill stringent requirements regarding electrical insulation between their components or between the power semiconductor package and its environment. In the case of insufficient insulation, failures like for example leakage currents or electrical shorts may occur. In order to provide sufficient insulation, a power semiconductor package may be required to have a certain minimum creepage distance along an outer surface of the power semiconductor package. For example, the minimum creepage distance may have to insulate against a potential difference of 600V or more, or even 1 kV or more. Improved power semiconductor packages and improved methods for fabricating power semiconductor packages may exhibit improved insulating capabilities as well as further advantages.

### SUMMARY

Various aspects pertain to a method for fabricating a power semiconductor package, the method comprising: providing a leadframe comprising a die pad and a frame, wherein the die pad is connected to the frame by at least one tie bar, attaching a semiconductor die to the die pad, laser cutting through the at least one tie bar, thereby forming a cut surface, and after the laser cutting, molding over the die pad and the semiconductor die, wherein the cut surface is completely covered by molding compound.

Various aspects pertain to a power semiconductor package, comprising: a die pad comprising at least one tie bar stump, wherein a cut surface is arranged at the end of the at least one tie bar stump, a semiconductor die attached to the die pad, and an encapsulation encapsulating the semiconductor die, wherein the encapsulation completely covers the cut surface, and wherein the cut surface comprises a microstructure fabricated by laser cutting.

### BRIEF DESCRIPTION OF THE DRAWINGS

The accompanying drawings illustrate examples and together with the description serve to explain principles of the disclosure. Other examples and many of the intended advantages of the disclosure will be readily appreciated as they become better understood by reference to the following detailed description. The elements of the drawings are not necessarily to scale relative to each other. Identical reference numerals designate corresponding similar parts.

FIGS. 1A and 1B show a top view and a sectional view of a power semiconductor package comprising a tie bar stump, wherein an encapsulation completely covers a cut surface of the tie bar stump.

FIG. 2 shows a top view of a further power semiconductor package, wherein external leads are exposed from the encapsulation but the cut surface of the tie bar stumps is not.

FIGS. 3A and 3B show a top view and a detail view of a further power semiconductor package, wherein a creepage distance between two external leads is shown in the detailed view.

FIGS. 4A to 4E show the power semiconductor package of FIG. 2 in various stages of fabrication according to an exemplary method for fabricating power semiconductor devices.

FIGS. 5A to 5C show exemplary tie bars which may be used in power semiconductor packages, according to an example.

FIG. 6 shows an exemplary die pad which may be used in power semiconductor packages, according to an example.

FIGS. 7A to 7C show a method for fabricating an encapsulation of a power semiconductor package, wherein retractable pins are used to hold a die pad in place during molding.

FIG. 8 shows an apparatus for laser cutting which may be used in the fabrication of a power semiconductor package.

FIG. 9 is a flow chart of an exemplary method for fabricating power semiconductor packages.

### DETAILED DESCRIPTION

In the following detailed description, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. Other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The examples of a power semiconductor package may use various types of semiconductor chips or circuits incorporated in the semiconductor chips, among them AC/DC or DC/DC converter circuits, power MOS transistors, power Schottky diodes, JFETs (Junction Gate Field Effect Transistors), power bipolar transistors, logic integrated circuits, analogue integrated circuits, power integrated circuits, etc.

The power semiconductor packages described below may include one or more semiconductor chips. By way of example, one or more power semiconductor chips may be included. Further, one or more logic integrated circuits may be included in the packages. The logic integrated circuits may be configured to control the integrated circuits of other semiconductor chips, for example the integrated circuits of power semiconductor chips. The logic integrated circuits may be implemented in logic chips.

The semiconductor chip(s) may be covered with an encapsulation material. The encapsulation material may be electrically insulating. The encapsulation material may comprise or be made of any appropriate plastic or polymer material such as, e.g., a duroplastic, thermoplastic or thermosetting material or laminate (prepreg), and may e.g. contain filler materials.

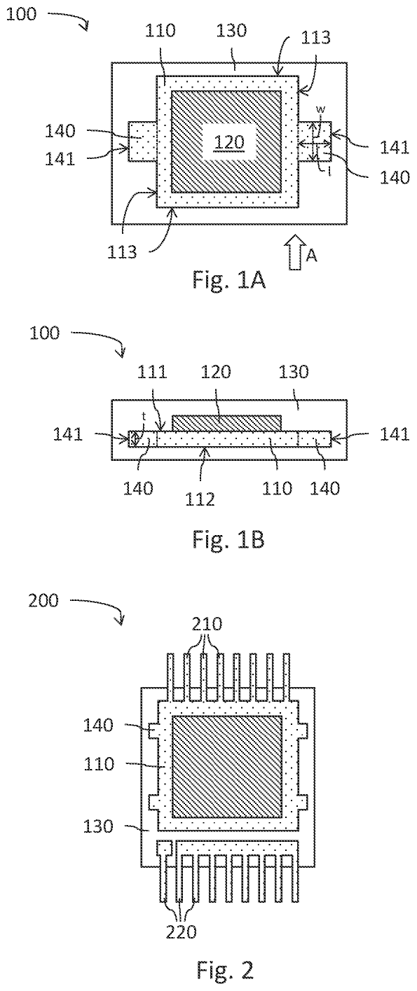

FIGS. 1A and 1B show a power semiconductor package 100 comprising a die pad 110, a semiconductor die 120 attached to the die pad 110 and an encapsulation 130 encapsulating the semiconductor die 120. FIG. 1A shows a top view and FIG. 1B shows a side view along arrow A in FIG. 1A.

The die pad 110 comprises at least one tie bar stump 140. In the example shown in FIGS. 1A and 1B, the power semiconductor package 100 comprises two tie bar stumps 140. The power semiconductor package 100 may comprise any suitable number of tie bar stumps 140, e.g. one, two, three, four or more than four.

The tie bar stump 140 comprises a cut surface 141 which is arranged at the end of the tie bar stump 140. The cut surface 141 may for example be arranged such that it faces away from the die pad 110. The cut surface 141 comprises a microstructure fabricated by laser cutting. In other words, the tie bar stump 140 is a leftover of a tie bar which has been cut through by a laser, thereby fabricating the tie bar stump 140 with the cut surface 141. As shown in FIGS. 1A and 1B, the encapsulation 130 completely covers the cut surface 141.

The die pad 110 may for example be part of a leadframe. The power semiconductor package 100 may e.g. comprise external contacts (not shown in FIGS. 1A and 1B9 which may be part of the same leadframe. The die pad 110 may comprise or consist of any suitable metal or metal alloy, e.g. Al, Fe or Cu. The tie bar stump 140 may be contiguous with the die pad 110, meaning that the die pad 110 and the tie bar stump 140 are fabricated from a single part (this is indicated by dashed lines separating the die pad 110 and the tie bar stump 140).

The die pad 110 may comprise a first main side 111 and an opposing second main side 112, wherein the semiconductor die 120 is arranged on the first main side 111. The die pad 110 may further comprise lateral sides 113 connecting the first and second main sides 111, 112 and the tie bar stump 140 may be arranged on and extend out of a lateral side 113.

The encapsulation 130 may cover the first main side and the lateral sides 113 of the die pad 110. According to an example, the second main side 112 is exposed from the encapsulation 130. The exposed second main side 112 may for example be configured as an external contact of the power semiconductor package 100 or it may be configured to be coupled to a heatsink. According to another example, the second main side 112 as well may be covered by the encapsulation 130, as shown in FIG. 1B.

The semiconductor die 120 may for example be a power semiconductor die, configured to operate with a high electrical current and/or a high voltage. A power terminal of the semiconductor die 120, e.g. a source, drain, emitter, or collector terminal, may be electrically coupled to the die pad 110. The power semiconductor package 100 may comprise a single semiconductor die 120 or it may comprise several semiconductor dies 120. The several semiconductor dies 120 may be coupled together, for example to form a half-bridge circuit, an inverter circuit, a converter circuit, etc.

The encapsulation 130 may for example comprise a molded body and/or a hard plastic frame. The encapsulation may comprise or consist of a dielectric, e.g. a polymer or polymer composition. The encapsulation 130 may be configured to protect the semiconductor die 120 from environmental influences and it may also be configured to electrically insulate different parts of the power semiconductor package 100 from one another.

According to an example, the encapsulation 130 completely covers the semiconductor die 120, the first main side 111 and all lateral sides 113 of the die pad 110. However, the power semiconductor package 100 may comprise external contacts (not shown in FIGS. 1A and 1B) which are exposed from the encapsulation 130 and which are electrically coupled to the semiconductor die 110.

The tie bar stump 140 may have any suitable dimensions. For example, the tie bar stump 140 may have a width w of less than or about 0.5 mm, more than 0.5 mm, more than 1 mm, or more than 2 mm. The tie bar stump 140 may for example have a length 1 of less than or about 0.1 mm, more than 0.1 mm, more than 0.2 mm, more than 0.5 mm, or more than 1 mm. The tie bar stump 140 (and the die pad 110) may for example have a thickness t of less than or about 0.1 mm, more than 0.1 mm, more than 0.2 mm, more than 0.5 mm, or more than 1 mm.

The cut surface 141 may be arranged perpendicular or essentially perpendicular to the first and second main sides 111, 112. The cut surface 141 may be parallel to the respective lateral side 113. The microstructure of the cut surface 141 (which as mentioned above is due to laser cutting) may be different from the microstructure of other surfaces of the power semiconductor package 100. The microstructure of the cut surface 141 may in particular be different from the microstructures of the first and second main sides 111, 112 and the lateral sides 113. Fabricating the die pad 110 may e.g. comprise stamping or mechanically cutting the die pad 110 out of a metal sheet. The lateral sides 113 may therefore comprise a microstructure fabricated by stamping or mechanical cutting which to the person skilled in the art is noticeably different from a microstructure fabricated by laser cutting.

FIG. 2 shows a top view of a further power semiconductor package 200 which may be similar to or identical with the power semiconductor package 100, except for the differences described in the following.

The power semiconductor package 200 comprises all parts of the power semiconductor package 100 and it additionally comprises first leads 210 and second leads 220. The first and second leads 210, 220 may for example be configured as external contacts of the power semiconductor package 200. The first leads 210 may for example be contiguous with the die pad 110 and the tie bar stump 140. The second leads 220 may e.g. be separate from the die pad 110 and tie bar stump 140 and may be electrically coupled to the semiconductor die 120 by bond wires, ribbons, or contact clips. The first and second leads 210, 220 may e.g. be of the gull-wing type or any other suitable type of lead.

As shown in FIG. 2, the first and second leads 210, 220 may be arranged on lateral sides 113 of the die pad 110 which do not comprise a tie bar stump 140. However, it is also possible that at least some leads are arranged on the same lateral side 113 as a tie bar stump 140. A tie bar stump 140 may for example be arranged between two leads.

As shown in FIG. 2, the power semiconductor package 200 may comprise four tie bar stumps 140 which may e.g. be arranged in pairs on opposite lateral sides 113 of the die pad 110. However, the power semiconductor package 200 may also comprise any other number of tie bar stumps 140. Furthermore, not all of the tie bar stumps 140 need to be contiguous with the die pad 110. Instead, one or more of the tie bar stumps 140 may be contiguous with other leadframe parts of the power semiconductor package 200, e.g. with the second leads 220.

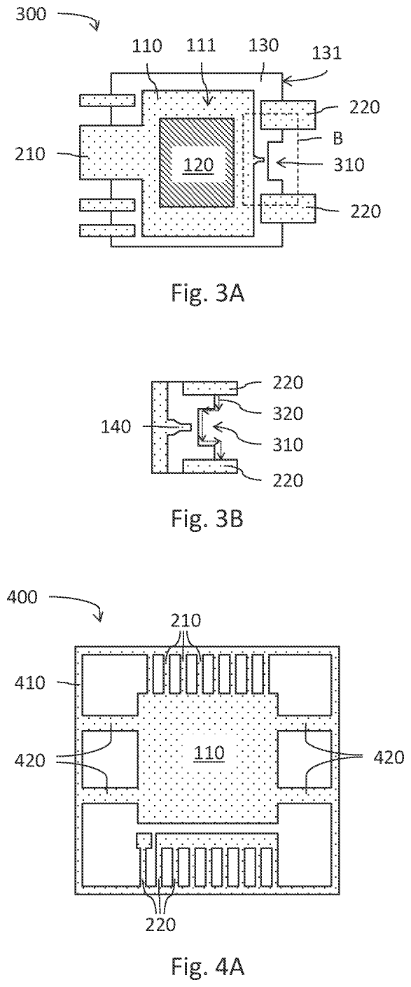

FIGS. 3A and 3B show a further power semiconductor package 300 which may be similar to or identical with the power semiconductor packages 100 and 200. FIG. 3A shows a top view of the whole power semiconductor package 300 and FIG. 3B shows a detail view of section B in FIG. 3A.

The power semiconductor package 300 comprises a recess 310 in the encapsulation 130, for example in a lateral side 131 of the encapsulation 130. As seen from above the first side 111 of the die pad 110, an outline of the encapsulation 130 is shifted inwards in the recess 310 with respect to the rest of the lateral side 131.

The recess 310 may be arranged between two second leads 220 of the power semiconductor package 300. The recess 310 may be configured to increase a creepage distance 320 between the two second leads 220 on either side of the recess 310. The required creepage distance 320 may depend on the voltage the semiconductor package 300 has to operate with: a high voltage may require a longer creepage distance 320 than a comparatively lower voltage. The creepage distance 320 may for example be 0.5 mm or more, 1 mm or more, 2 mm or more, 4 mm or more, 5 mm or more, 6 mm or more, 8 mm or more, or 9 mm or more, or 10 mm or more, or 20 mm or more, or 40 mm or more, or 100 mm or more. For example, the size of the creepage distance 320 in combination with the dielectric properties of the encapsulation 130 may allow for a potential difference between the two second leads 220 of 1 kV or more, or 1.2 kV or more before a flashover occurs.

The tie bar stump 140 may be arranged such that it faces the recess 310. However, the tie bar stump 140 is not exposed from the encapsulation 130 in the recess 310 but the encapsulation 130 completely covers it, including the cut surface 141. If the tie bar stump 140 were exposed from the encapsulation then it would cut in half the creepage distance 320 and consequently the potential difference that could be applied to the two second leads 220.

According to an example, the recess 310 as well as the tie bar stump 140 facing the recess 310 are not arranged between two second leads 220 but between a first lead 210 and a second lead 220 or between any other electrically conductive parts of the power semiconductor package 330 that are exposed from the encapsulation 130 at the lateral side 131.

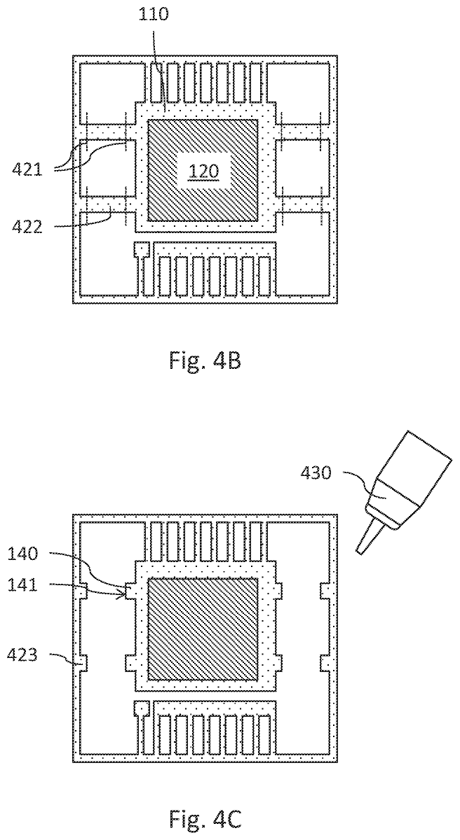

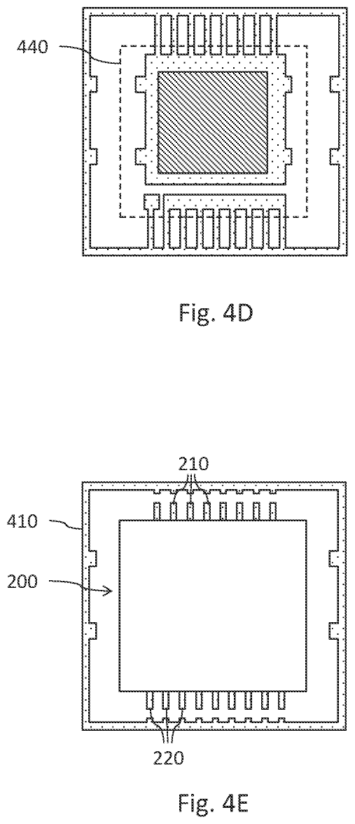

FIGS. 4A to 4E show the power semiconductor package 200 in various stages of fabrication, according to an exemplary method for fabricating a power semiconductor package. According to an example, the power semiconductor packages 100 and 300 can be fabricated in a similar manner.

As shown in FIG. 4A, a leadframe 400 comprising the die pad 110 and a frame 410 is provided. The frame 410 may surround the die pad 110 on four sides and it may be configured to be cut away during fabrication of the power semiconductor package 200. The die pad 110 is connected to the frame 410 by at least one tie bar 420, for example by four tie bars 420 as shown in FIG. 4A.

As shown in FIG. 4B, the semiconductor die 120 is attached to the die pad 110. This may for example comprise soldering, sintering or gluing with a conductive glue the semiconductor die 120 to the die pad 110.

As shown in FIG. 4C, the at least one tie bar 420 is cut through with a laser, thereby fabricating the at least one tie bar stump 140 and the respective cut surface 141. According to an example, laser cutting through the tie bar 420 comprises laser cutting the tie bar at two different locations, e.g. close to both ends of the tie bar 420. Each tie bar 420 may for example be cut along the cutting lines 421 shown in FIG. 4B. In this manner, a length of tie bar 422 between the cutting lines 421 is cut away completely. The length of tie bar 422 may e.g. be less than or about 1 mm long, more than 1 mm long, more than 1.5 mm long, more than 2 mm long, or more than 3 mm long. Cutting away along the cutting lines 421 may also fabricate further tie bar stumps 423 contiguous with the frame 410, wherein each further tie bar stump 423 faces a respective tie bar stump 140.

Any suitable laser 430 may be used for laser cutting through the tie bar 420. For example, the laser 430 may be a Yb fiber laser with e.g. a power density of about 10 kW/mm and a pulse time in the nanoseconds to milliseconds range.

According to an example, after laser cutting through the tie bar 420, the fabricated tie bar stump 140 may comprise a burr at the cut surface 141. Such a burr may e.g. comprise a sharp and/or rugged edge to which the encapsulation 130 does not readily adhere, leading to delamination issues. The burr may therefore be removed from the cut surface 141 prior to applying the encapsulation 130. This may e.g. be done using the laser 430, for example in a subsequent laser application process, after the laser cutting. In this subsequent laser application process, the laser 430 may be used with different settings, e.g. with a reduced power density. However, it is also possible that the settings of the laser 430 and/or the material of the tie bar 420 is chosen such that no burr is created by the laser cutting process.

According to an example, the die pad 110 is still mechanically connected to the frame 410 by the first leads 210 after the tie bar 420 has been cut through. The first leads 210 may therefore be designed with enough stability to mechanically support the die pad 110 in this stage of fabrication.

According to an example, the laser cutting is performed after the semiconductor die 120 has been attached to the die pad 110. The laser cutting may in particular be performed after coupling an electrical connector to the semiconductor die 120. Such an electrical connector may e.g. be used to connect a terminal of the semiconductor die 120 to an external contact of the power semiconductor package 200 (not shown in the Figures). The electrical connector may e.g. comprise a bond wire, a ribbon, or a contact clip.

As shown in FIG. 4D, after laser cutting the tie bars 420, the encapsulation 130 is fabricated. This may comprise molding over the die pad 110 and the semiconductor die 120 using a molding cavity 440 of a molding tool. The die pad 110, the semiconductor die 120 and the tie bar stump(s) 140 are completely arranged within the molding cavity 440, such that the cut surface 141 can be completely covered by molding compound. The first and second leads 210, 220 on the other hand may stick out of the molding cavity 440.

As shown in FIG. 4E, after fabricating the encapsulation 130, the power semiconductor package 200 may be singulated from the frame 410 by cutting through the leads 210, 220. Since the tie bars 420 have already been cut through prior to fabricating the encapsulation 130, no tie bars need to be cut at this stage in order to singulate the power semiconductor package 200 from the frame 410.

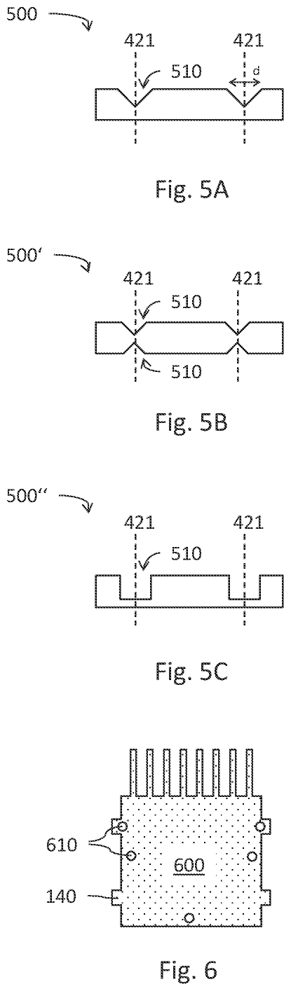

FIGS. 5A to 5C show exemplary tie bars 500, 500′ and 500″, wherein each one of the tie bars 500, 500′ and 500″ may be used in place of the tie bar 420.

The tie bars 500, 500′ and 500″ each comprise at least one notch 510, wherein a thickness of the tie bars 500, 500′ and 500″ is reduced within the notch. Cutting through the tie bars 500, 500′ and 500″ within a notch 510 may be faster and create fewer residues compared to cutting at a location with a higher thickness. Within the notch 510 the thickness of the tie bars 500, 500′ and 500″ may for example be reduced by 20% or more, 40% or more, 60% or more, or 80% or more. The notch 510 may for example have a width d of less than or about 0.2 mm, more than 0.2 mm, more than 0.4 mm, more than 0.8 mm, or more than 1 mm.

According to an example, the notch 510 may be fabricated by a stamping or an etching process. The notch 510 may for example be fabricated prior to arranging the semiconductor die 120 on the die pad 110, e.g. during fabrication of the leadframe 400.

The notch 510 may have any suitable shape, e.g. a V-shape as shown in FIGS. 5A and 5B or it may have a flat bottom as shown in FIG. 5C. Furthermore, as shown in FIG. 5B, notches 510 may be arranged as “double-notches” on opposite sides of the tie bar, facing each other such that a single cutting line 421 extends through a double-notch.

In the case that the power semiconductor packages 100, 200 or 300 were fabricated using the tie bars 500, 500′ or 500″, the tie bar stump 140 may comprise a stepped end face. In the case of the tie bars 500 and 500′, a first part of the end face may comprise a slanting surface and a second part may comprise the cut surface 141, arranged perpendicular to the first and second main sides 111, 112 of the die pad 110. In the case of the tie bar 500″, the first part of the end face may comprise a recessed surface arranged perpendicular to the first and second main sides 111, 112 and the second part may comprise the cut surface 141. In both cases, the surface of the first part may comprise a microstructure fabricated by mechanical stamping or chemical etching, whereas the cut surface 141 comprises a microstructure fabricated by laser cutting, as mentioned previously.

FIG. 6 shows an exemplary die pad 600 which may be used instead of the die pad 110 in the power semiconductor packages 100, 200 and 300. The die pad 600 may be similar to or identical with the die pad 110, except that it additionally comprises at least one mold locking feature 610.

The mold locking feature is configured to improve an adhesion of the encapsulation 130 to the die pad 600. The mold locking feature 610 may for example comprise an indention or a through hole in the die pad 600, wherein an indention only partially extends through the die pad 600 and wherein a through hole completely extends through the die pad 600. The mold locking feature 610 may have any suitable shape and any suitable dimensions, e.g. a round shape or a rectangular shape and a diameter of 2 mm or less, or 1 mm or less.

The mold locking feature 610 may be located at any suitable position on the die pad 600 that comes into direct contact with the encapsulation 130. The mold locking feature 610 may for example be arranged close to an edge of the die pad 600 or it may be arranged on the tie bar stump 140.

The mold locking feature 610 may e.g. be fabricated by laser cutting the die pad. The mold locking feature 610 may e.g. be fabricated using the same laser 430 that is also used for cutting through the tie bars 420. The mold locking feature 610 may e.g. be fabricated in the same process in which the tie bars 420 are cut through. The mold locking feature 610 may comprise a cut surface comprising a microstructure fabricated by laser cutting (similar to the microstructure of the cut surface 141 of the tie bar stump 140).

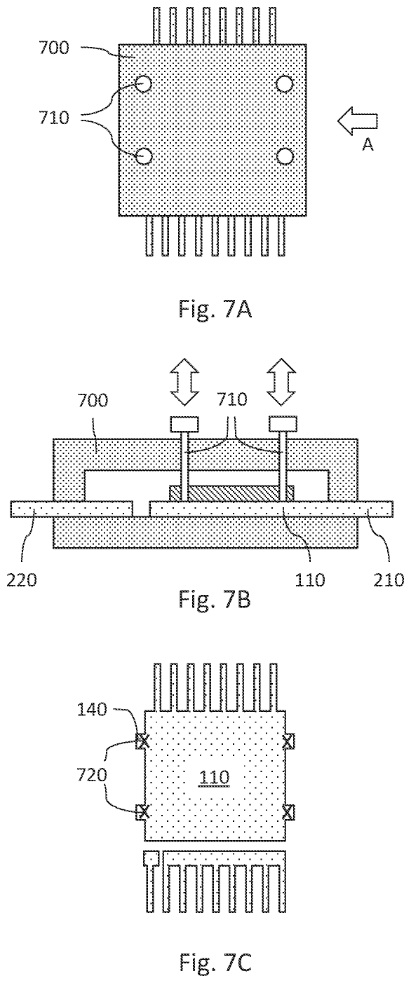

FIGS. 7A to 7C show an exemplary molding process which may e.g. be used for fabricating the encapsulation 130 as shown in FIG. 4D. For simplicity's sake, the frame 410 is not shown in FIG. 7A.

As shown in FIGS. 7A and 7B, a molding tool 700 with retractable pins 710 is used in this exemplary molding process. FIG. 7A shows a top view and FIG. 7B shows a sectional view from the direction of arrow A in FIG. 7A. The retractable pins 710 may be configured to hold the die pad 110 in place during the molding process. This may be necessary because the die pad 110 is not held in place by the tie bars 420, since the tie bars 420 have already been cut away at this stage.

The retractable pins 710 may e.g. be lowered down unto the die pad 110 after the die pad 110 has been placed into the molding tool 700. The retractable pins 710 may be pulled out again after the molding tool 700 has been filled with molding material. According to an example, the retractable pins 710 are only pulled out once the molding material has hardened sufficiently.

According to an example, holes that are left in the encapsulation 130 where the retractable pins 710 used to be are subsequently filled up, e.g. by injecting molding material. According to another example, these holes do not inhibit the functionality of the power semiconductor package 100, 200 or 300 and therefore need not be filled up.

FIG. 7C shows possible points of contact 720 of the retractable pins 710 on the die pad 110. The points of contact 720 may for example be arranged on or close to the tie bar stumps 140 or at any other suitable location on the die pad 110. The points of contact 720 may in particular be chosen such that the retractable pins 710 touch the die pad 110 but not the semiconductor die 120.

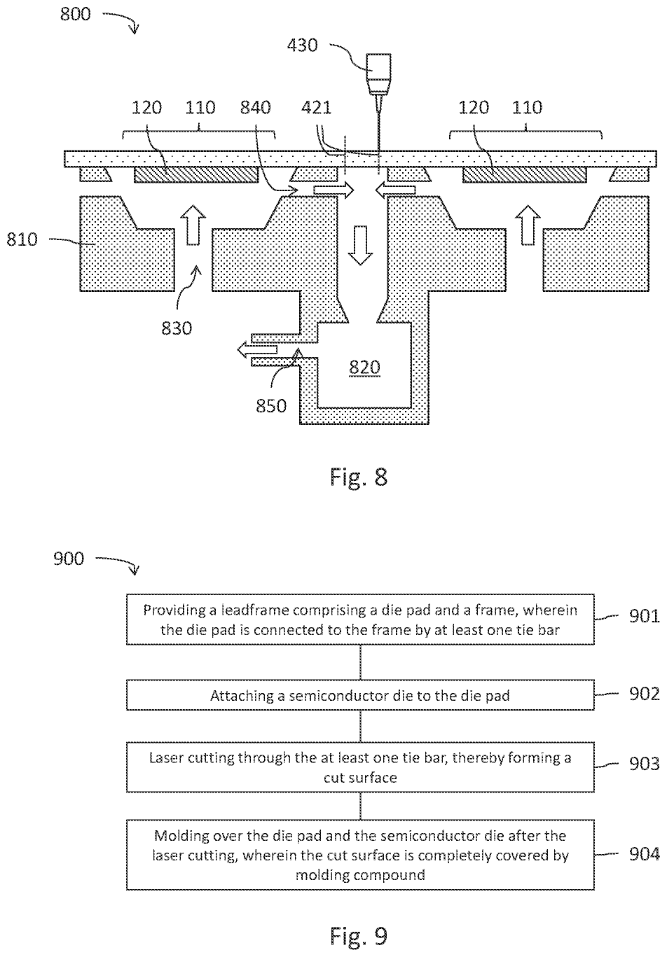

FIG. 8 shows a laser cutting apparatus 800 which, according to an example, may be used for cutting through the tie bars 420. The laser cutting apparatus 800 may also be used for fabricating the mold locking feature 610.

The laser cutting apparatus 800 comprises a carrier 810 configured for carrying a leadframe like the leadframe 400. The laser cutting apparatus 800 further comprises a waste collector 820 for collecting waste material that is cut away from the leadframe 400 by the laser 430, e.g. the length of tie bar 422. Gas inlets 830, gas channels 840 and gas outlet 850 are configured to direct a gas stream towards the waste collector 820. The gas stream may help with transporting waste material into the waste collector 820. The gas stream may e.g. comprise or consist of N, air or any other suitable gas. According to an example, the gas outlet 850 is coupled to a pump for creating a negative pressure, thereby sucking in the gas stream.

The laser cutting apparatus 800 may not only be configured for collecting macroscopic waste like the length of tie bar 422 in the waste collector 820. It may also be configured for removing microscopic residuals of the laser cutting procedure from the leadframe 400 and semiconductor die 120 and collecting them in the waste collector 820 by means of the gas stream. This may help with keeping clean the surfaces of all components of the power semiconductor package 100, 200 and 300 and thereby assure a proper functionality of the fabricated power semiconductor package.

FIG. 9 is a flow chart of an exemplary method 900 for fabricating a power semiconductor package. The method 900 may for example be used for fabricating the power semiconductor packages 100, 200 and 300.

The method 900 comprises at 901 an act providing a leadframe comprising a die pad and a frame, wherein the die pad is connected to the frame by at least one tie bar, at 902 an act of attaching a semiconductor die to the die pad, at 903 an act of laser cutting through the at least one tie bar, thereby forming a cut surface, and at 904 an act of molding over the die pad and the semiconductor die after the laser cutting, wherein the cut surface is completely covered by molding compound.

In the following, the power semiconductor package and the method for fabricating a power semiconductor package are further explained using specific examples.

Example 1 is a method for fabricating a power semiconductor package, the method comprising: providing a leadframe comprising a die pad and a frame, wherein the die pad is connected to the frame by at least one tie bar, attaching a semiconductor die to the die pad, laser cutting through the at least one tie bar, thereby forming a cut surface, and after the laser cutting, molding over the die pad and the semiconductor die, wherein the cut surface is completely covered by molding compound.

Example 2 is the method of example 1, further comprising: laser cutting a mold locking feature into the die pad, wherein the mold locking feature comprises a through-hole or a cavity, and filling the mold locking feature with the molding compound.

Example 3 is the method of example 1 or 2, wherein the laser cutting comprises laser cutting through the at least one tie bar in two different locations such that a length of tie bar is cut away completely.

Example 4 is the method of example 3, further comprising: using an air stream, a gas stream, or a negative pressure in order to remove the length of tie bar from the leadframe.

Example 5 is the method of one of the preceding examples, further comprising: after the laser cutting, removing a burr from the cut surface with the laser.

Example 6 is the method of one of the preceding examples, wherein the at least one tie bar comprises at least one notch, and wherein the laser cutting is performed in the at least one notch.

Example 7 is the method of one of the preceding examples, wherein the leadframe further comprises leads contiguous with the die pad, and wherein during the molding the die pad is connected to the frame by the leads.

Example 8 is the method of example 7, further comprising: after the molding, singulating the power semiconductor package from the frame by cutting through the leads.

Example 9 is the method of one of the preceding examples, wherein the molding is performed using a molding tool with retractable pins, wherein the retractable pins are configured to fix the die pad in place, and wherein the retractable pins are retracted during the molding.

Example 10 is the method of one of the preceding examples, further comprising: before the laser cutting, coupling an electrical connector to the semiconductor die, wherein the electrical connector comprises a bond wire, a ribbon, or a contact clip.

Example 11 is a power semiconductor package, comprising: a die pad comprising at least one tie bar stump, wherein a cut surface is arranged at the end of the at least one tie bar stump, a semiconductor die attached to the die pad, and an encapsulation encapsulating the semiconductor die, wherein the encapsulation completely covers the cut surface, and wherein the cut surface comprises a microstructure fabricated by laser cutting.

Example 12 is the power semiconductor package of example 11, wherein the at least one tie bar stump faces a first lateral side of the encapsulation, and wherein no metal part is exposed from the encapsulation at the first lateral side.

Example 13 is the power semiconductor package of example 11 or 12, further comprising: at least one through-hole extending through the die pad, wherein the through-hole is filled with the material of the encapsulation, and wherein the through-hole comprises a further cut surface comprising a microstructure fabricated by laser cutting.

Example 14 is the semiconductor package of one of examples 11 to 13, wherein the at least one tie bar stump comprises a notch, and wherein the cut surface is arranged in the notch.

Example 15 is the semiconductor package of one of examples 11 to 14, wherein the cut surface is free of any burr.

Example 16 is an apparatus comprising means for performing the method of anyone of examples 1 to 10.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A method for fabricating a power semiconductor package, the method comprising:
providing a leadframe comprising a die pad and a frame, wherein the die pad is connected to the frame by at least one tie bar;
attaching a semiconductor die to the die pad;
laser cutting through the at least one tie bar, thereby forming a cut surface; and
after the laser cutting, molding over the die pad and the semiconductor die, wherein the cut surface is completely covered by molding compound.

2. The method of claim 1, further comprising:
laser cutting a mold locking feature into the die pad, wherein the mold locking feature comprises a through-hole or a cavity; and
filling the mold locking feature with the molding compound.

3. The method of claim 1, wherein the laser cutting comprises laser cutting through the at least one tie bar in two different locations such that a length of tie bar is cut away completely.

4. The method of claim 3, further comprising:
using an air stream, a gas stream, or a negative pressure to remove the length of tie bar from the leadframe.

5. The method of claim 1, further comprising:
after the laser cutting, removing a burr from the cut surface with the laser.

6. The method of claim 1, wherein the at least one tie bar comprises at least one notch, and wherein the laser cutting is performed in the at least one notch.

7. The method of claim 1, wherein the leadframe further comprises leads contiguous with the die pad, and wherein during the molding the die pad is connected to the frame by the leads.

8. The method of claim 7, further comprising:
after the molding, singulating the power semiconductor package from the frame by cutting through the leads.

9. The method of claim 1, wherein the molding is performed using a molding tool with retractable pins, wherein the retractable pins are configured to fix the die pad in place, and wherein the retractable pins are retracted during the molding.

10. The method of claim 1, further comprising:
before the laser cutting, coupling an electrical connector to the semiconductor die, wherein the electrical connector comprises a bond wire, a ribbon, or a contact clip.

11. A power semiconductor package, comprising:
a die pad comprising at least one tie bar stump, wherein a cut surface is arranged at the end of the at least one tie bar stump;
a semiconductor die attached to the die pad; and
an encapsulation encapsulating the semiconductor die, wherein the encapsulation completely covers the cut surface, and
wherein the cut surface comprises a laser-cut microstructure.

12. The power semiconductor package of claim 11, wherein the at least one tie bar stump faces a first lateral side of the encapsulation, and wherein no metal part is exposed from the encapsulation at the first lateral side.

13. The power semiconductor package of claim 11, further comprising:
at least one through-hole extending through the die pad, wherein the at least one through-hole is filled with a material of the encapsulation, and wherein the at least one through-hole comprises a further cut surface comprising a laser-cut microstructure.

14. The semiconductor package of claim 11, wherein the at least one tie bar stump comprises a notch, and wherein the cut surface is arranged in the notch.

15. The semiconductor package of claim 11, wherein the cut surface is free of any burr.
